(19) United States
(12) Patent Application Publication
(10) Pub. No.: US 2022/0359758 A1
(43) Pub. Date: Nov. 10, 2022

(54) METAL OXIDE THIN FILM TRANSISTORS WITH MULTI-COMPOSITION GATE DIELECTRIC

(71) Applicant: Intel Corporation, Santa Clara, CA (US)

(72) Inventors: Shailesh Kumar Madisetti, Hillsboro, OR (US); Chieh-Jen Ku, Hillsboro, OR (US); Wen-Chiang Hong, Tigard, OR (US); Pei-Hua Wang, Hillsboro, OR (US); Cheng Tan, Hillsboro, OR (US); Harish Ganapathy, Portland, OR (US); Bernhard Sell, Portland, OR (US); Lin-Yung Wang, Hillsboro, OR (US)

(73) Assignee: Intel Corporation, Santa Clara, CA (US)

(21) Appl. No.: 17/308,853

(22) Filed: May 5, 2021

(51) Int. Cl. H01L 29/786; H01L 29/66

(52) U.S. Cl. CPC H01L 29/7869; H01L 29/78696; H01L 29/66742

(57) ABSTRACT

Transistors with metal oxide channel material and a multi-composition gate dielectric. A surface of a metal oxide gate dielectric may be nitrided before deposition of a metal oxide channel material, for example to reduce gate capacitance of a TFT. Breakdown voltage and/or drive current of a TFT can be increased through the introduction of an additional metal oxide and/or nitride between the gate electrode and a metal oxide gate dielectric. The introduction of an intervening layer between two layers of a metal oxide gate dielectric can also increase breakdown voltage and/or drive current of a TFT.

### BACKGROUND

A thin-film transistor (TFT) is a class of field-effect transistors (FETs) in which the channel semiconductor material is a deposited thin film rather than a surface layer of a substantially monocrystalline substrate material. Group IV materials (e.g., Si, Ge) may be employed in TFTs, but metal oxide semiconductors, such as those including In and Ga, are also promising channel materials for TFTs. Metal oxide semiconductors have the potential to be deposited at low temperatures (e.g., below 450° C.). If a thin film semiconductor material can be deposited at sufficiently low temperatures, one or more transistor device levels may be integrated monolithically with one or more other device levels that may include devices, such as CMOS FETs that have been fabricated within an underlying bulk semiconductor layer, other TFTs, or memory devices. For example, embedded dynamic random access memory (eDRAM) may be monolithically integrated with CMOS circuitry and TFTs may control access and/or addressing of the memory array.

However, many TFTs with metal oxide channel materials display relatively low breakdown voltages (e.g., BV_{DS}) potentially limiting their application. For example, it is challenging to achieve a BV_{DS} exceeding 1V for TFTs with a channel material of In, Ga, Zn and O (IGZO). A breakdown voltage in the range of 1.5-2V would increase the commercial application of IGZO TFTs.

Structural constraints on TFTs can lead to gate capacitance (C_{g}) values that can result in significant RC delay in some circuitry. In eDRAM circuitry, for example, TFT capacitance can be a significant contribution to RC delay that limits the memory array read/write speed. For such circuitry, it is challenging to reduce gate capacitance without degrading retention time, for example as a result of inducing greater gate leakage.

Techniques for forming a thin film of metal oxide semiconductor material that can overcome one or more of the above issues, and the TFT structures resulting from such techniques, would therefore be commercially advantageous.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating methods of fabricating thin film transistor including a multi-composition gate dielectric, in accordance with some embodiments;

FIG. 2 is a plan view of a thin film transistor structure including a multi-composition gate dielectric, in accordance with some embodiments;

FIG. 3 is a cross sectional view of the transistor structure along the A-A′ line introduced in FIG. 2, in accordance with some bottom-gate embodiments;

FIG. 4 is a graph illustrating compositional variation within a gate dielectric of a thin film transistor structure, in accordance with some embodiments;

FIG. 5 is a flow diagram illustrating methods of fabricating thin film transistor including a multi-composition gate dielectric, in accordance with some embodiments;

FIG. 6 is a cross sectional view of the transistor structure along the A-A′ line introduced in FIG. 2, in accordance with some bottom-gate embodiments;

FIG. 7 is a graph illustrating compositional variation within a gate dielectric of a thin film transistor structure, in accordance with some embodiments;

FIG. 8 is a flow diagram illustrating methods of fabricating thin film transistor including a multi-composition gate dielectric, in accordance with some embodiments;

FIG. 9 is a cross sectional view of the transistor structure along the A-A′ line introduced in FIG. 2, in accordance with some bottom-gate embodiments;

FIG. 10 is a cross sectional view of the transistor structure along the A-A′ line introduced in FIG. 2, in accordance with some top-gate embodiments;

FIG. 11 is a cross-sectional view of a 3DIC structure including TFT circuitry over CMOS FET circuitry, in accordance with some embodiments;

FIG. 12 illustrates a system employing an IC including TFT circuitry over CMOS FET circuitry, in accordance with some embodiments; and

FIG. 13 is a functional block diagram illustrating an electronic computing device, in accordance with some embodiments.

### DETAILED DESCRIPTION

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the explicit context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. The term “substantially” means there is no more than incidental variation from a target value. For example, a composition that is substantially a first constituent means the composition only includes trace levels of any constituent other than the first constituent.

Described herein are transistor structures, and more particularly thin film transistors (TFTs), that have a metal oxide channel material. The metal oxide channel material may be a binary, ternary, quaternary, or quinary alloy, for example. In some embodiments, the channel material includes In, Ga, Zn, and O (IGZO). The transistor structures further include a multi-composition gate dielectric that the inventors have found to increase breakdown voltage (e.g., BV_{DS}), and/or reduce gate capacitance (C_{g}), and/or increase greater drive current (Iₒₙ) of the transistor.

As described further below, in some bottom-gate TFT embodiments a surface of a metal oxide gate dielectric may be nitrided prior to the deposition of a metal oxide channel material. The inventors have found the introduction of nitrogen into a metal oxide gate dielectric can significantly reduce gate capacitance of the TFT without significant detriment to other transistor performance metrics, such as drive current. The inventors have also found that breakdown voltage and/or drive current of a TFT can be increased if the interface between the gate electrode and a metal oxide gate dielectric is improved through the introduction of an additional metal oxide and/or nitride between the gate electrode and the metal oxide gate dielectric. As described further below, the additional metal oxide and/or nitride may be transition from a metal of the gate electrode to an oxide of the gate dielectric. The inventors have further found that the introduction of an intervening layer between two layers of a metal oxide gate dielectric can also increase breakdown voltage and/or improve drive current. Accordingly, with the techniques exemplified herein, electrical performance of transistors including an exemplary metal oxide channel material can be improved relative to references having a substantially homogeneous gate dielectric material.

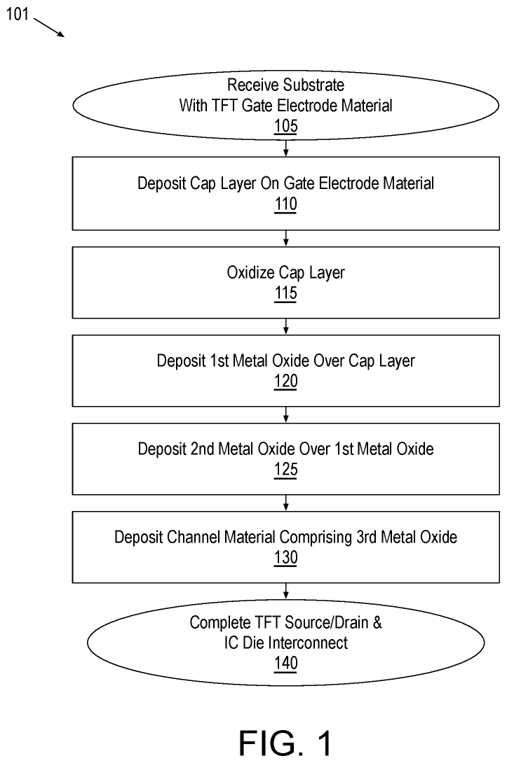

FIG. 1 is a flow diagram illustrating methods 101 for fabricating thin film transistor including a multi-composition gate dielectric, in accordance with some embodiments. Methods 101 begin at block 105 where a substrate is received. In exemplary embodiments, the substrate includes at least a gate electrode material that is to become the gate electrode of the thin film transistor fabricated through the practice of methods 101. Methods 101 are therefore suitable for a variety of bottom-gate transistor architectures. The gate electrode material may have been deposited upstream of methods 101 using any technique suitable for the composition, such as physical vapor deposition (PVD). In exemplary embodiments, the gate electrode material comprises at least one metal, such as Ti, W, Ta, or Al. In further embodiments, the gate electrode material further includes nitrogen (e.g., TiNₓ, WNₓ, TaNₓ, or AlNₓ) A gate electrode material may also include other constituents, such as, but not limited to, C.

Below the gate electrode material, the substrate may further include a monocrystalline semiconductor layer, such as a silicon layer, upon which front-end-of-line (FEOL) FETs have been fabricated upstream of methods 101. The substrate received at block 105 may therefore also include FEOL FETs of any architecture that are interconnected with one or more metallization levels into FEOL circuitry that is further interconnected to the thin film transistor formed by the practiced of methods 101. In some examples, the FEOL FETs include both n-type and p-type FETs interconnected into a CMOS FEOL circuit. Although the substrate received at block 105 may include FEOL FETs, the substrate may instead lack any prefabricated transistors or other microelectronic devices.

Methods 101 continue at block 110 where a cap layer is deposited on the gate electrode material. The cap layer may be deposited, for example, after the gate electrode material is first planarized with a CMP process. The cap layer may include the same metal as the gate electrode material. In some embodiments where the gate electrode material is a metal nitride, the cap layer deposited at block 110 is also a metal nitride. In some embodiments where the gate electrode material is TiNₓ, the cap layer deposited at block 110 is also TiNₓ. In other embodiments where the gate electrode material is WNₓ, the cap layer deposited at block 110 is also WNₓ. In other embodiments where the gate electrode material is TaNₓ, the cap layer deposited at block 110 is also TaNₓ. In other embodiments where the gate electrode material is AlNₓ, the cap layer deposited at block 110 is also AlNₓ. Nitrogen content of the cap layer may be greater than, or less than, that of the gate electrode material. Although the composition of the cap layer may be nearly the same as that of the gate electrode material, (e.g., to achieve a desired workfunction difference with a subsequently deposited semiconductor channel material), deposition of the cap layer can improve surface quality following planarization of the gate electrode material.

In exemplary embodiments, the cap layer is deposited with a cyclical atomic layer deposition process (ALD) in which a metal precursor is deposited during one phase of a cycle. Adsorbed metal precursor is then reacted with a ligand comprising nitrogen during another phase of the cycle through exposure of the metal precursor to one or more nitrogen precursor (e.g., NH₃, N₂O, N₂), which may be plasma activated, or not. For some exemplary low temperature embodiments, the ALD process is performed at a temperature not exceeding 450° C., and advantageously between 200 and 300° C. By controlling the number of ALD cycles, the cap layer may be deposited to a well-controlled thickness in the range of 1-5 nm.

Methods 101 continue at block 115 where oxygen is introduced into at least a surface of the cap layer. An oxidation is performed at block 115 to further condition the cap layer by increasing the oxygen content with proximity to the exposed surface(s). As a result of the oxidation, nitrogen content (e.g., at. %) within the cap layer accordingly decreases with proximity to the exposed surface. For embodiments where TiNₓ is deposited as a cap layer, at least a partial thickness of the TiNₓ is oxidized to form a layer of TiNₓO_{y} proximal to the expose surface of the cap layer (i.e., distal from the underlying gate electrode material). In another example where WNₓ is deposited as a cap layer, at least a partial thickness of the WNₓ is oxidized to form a layer WNₓO_{y} proximal to the surface of the cap layer. In another example where TaNₓ is deposited as a cap layer, at least a partial thickness of the TaNₓ is oxidized to form a layer TaNₓO_{y} proximal to the surface of the cap layer. In another example where AlNₓ is deposited as a cap layer, at least a partial thickness of the AlNₓ is oxidized to form a layer AlNₓO_{y} proximal to the surface of the cap layer.

Any low temperature oxidation process may be performed at block 115. In some exemplary embodiments, a plasma-based oxidation (e.g., O₂, CO₂) is performed at a temperature not exceeding 450° C., and advantageously between 200 and 300° C. An ozone treatment or a wet chemical oxidation (e.g., H₂O₂) may also be practiced, as well as plasma-free thermal anneals (e.g., in the presence of steam). The thickness of the cap layer oxidized at block 115 is dependent upon the duration and reactivity of the oxidation process performed at block 115. In exemplary embodiments, 1-2 nm of the cap layer is oxidized. Hence, the portion of the cap layer oxidized may vary from 100% for a cap layer that is 1-2 nm, to less than 50% for a cap layer that is 5 nm.

Methods 101 continue at block 120 where a metal oxide is deposited over the cap layer. In exemplary embodiments, the metal oxide deposited at block 120 comprises the same metal present in the cap layer. For example, titanium oxide may be deposited at block 120 for embodiments where TiNₓ is deposited as the cap layer, and then at least partially oxidized to form a layer of TiNₓO_{y}. In another example, tungsten oxide may be deposited at block 120 for embodiments where WNₓ is deposited as the cap layer, and then at least partially oxidized to form a layer WNₓO_{y}. In another example, tantalum oxide may be deposited at block 120 for embodiments where TaNₓ is deposited as the cap layer, and then at least partially oxidized to form a layer TaNₓO_{y}. In another example, aluminum oxide may be deposited at block 120 for embodiments where AlNₓ is deposited as the cap layer, and then at least partially oxidized to form a layer AlNₓO_{y}.

In exemplary embodiments, the metal oxide is deposited at block 120 with a cyclical ALD process in which the metal precursor is deposited during one phase of a cycle. Adsorbed metal precursor is then reacted with a ligand comprising oxygen during another phase of the cycle through exposure to one or more oxygen precursor (e.g., CO₂, O₂, H₂O), which may be plasma activated, or not. For some exemplary low temperature embodiments, the ALD process is performed at a temperature not exceeding 450° C., and advantageously between 200 and 300° C. By controlling the number of ALD cycles, the metal oxide may be deposited to a well-controlled layer thickness advantageously less than 2 nm (e.g., 0.5-1 nm). Whereas the oxidized cap layer can be expected to comprise some nitrogen (e.g., TiNₓO_{y}), the ALD process forms a metal oxide that is substantially free of nitrogen.

Methods 101 continue at block 125 where the gate stack is completed by depositing another metal oxide over the metal oxide formed at block 120. This additional metal oxide advantageously includes a second metal, such as one or more of Ga, Al, Hf, Zr, or Ta. This metal oxide is advantageously a high-k material having a relative permittivity (or dielectric constant) of at least 9. Exemplary metal oxides include GaOₓ(comprising predominantly Ga and O), AlOₓ (comprising predominantly Al and O), HfOₓ (comprising predominantly Hf and O), HfAlOₓ (comprising predominantly Al, Hf, and O). The metal oxide deposited at block 125 may further include silicon (i.e., a silicate), with one example being HfSiOₓ.

In exemplary embodiments, the metal oxide is deposited at block 125 with a cyclical ALD process in which the metal precursor is deposited during one phase of a cycle. Adsorbed metal precursor is then reacted through exposure to one or more oxygen precursor (e.g., N₂O, CO₂, O₂, H₂O), which may be plasma activated, or not. For some exemplary low temperature embodiments, the ALD process is performed at a temperature not exceeding 450° C., and advantageously between 200 and 300° C. By controlling the number of ALD cycles, the metal oxide may be deposited to a well-controlled layer thickness advantageously thicker than the first metal oxide (i.e., at least 2 nm).

With the gate stack complete, methods 101 continue at block 130 with deposition of the channel material. The channel material is also a metal oxide (i.e., a third metal oxide), but has semiconducting properties. The material deposited at block 130 may have any metal oxide composition that is suitable as channel region of a transistor, and is therefore referred to herein as “channel material.” In some embodiments, the channel material comprises a thin film that may be semiconducting substantially as-deposited, and/or following some subsequent activation process, such as a thermal anneal.

In accordance with some embodiments, metal oxide channel material is deposited at block 130 with PVD process during which a target of a desired alloy composition may be sputtered in an inert or reactive environment. In accordance with other embodiments, metal oxide channel material is deposited at block 130 with an ALD process. The ALD deposition process may entail cyclically depositing a precursor of each of a plurality of metals during a deposition phase of separate ALD cycles, and oxidizing the deposited precursor of each of a plurality of metals during an oxidation phase of each of the cycles.

Channel material may be deposited to a thicknesses in the range 2-20 nm, for example. At these thicknesses, an oxide semiconductor can have good transistor channel characteristics, for example offering high carrier mobility and a material band gap and resistivity that is tunable by a dopant that impacts the charge carrier (e.g., electron) concentrations. Oxide semiconductor materials primarily include one or more metals (M1, M1M2, M1M2M3, etc.) and oxygen. The metal(s) may be from the transition metals (e.g., IUPAC group 4-10) or post-transition metals (e.g., IUPAC groups 11-15). The metal oxide compounds may be suboxides (A₂O), monoxides (AO), binary oxides (AO₂), ternary oxides (ABO₃), and mixtures thereof, for example. In advantageous embodiments, the channel material deposited at block 130 includes oxygen and at least one of Mg, Cu, Zn, Sn, Ti, In, Ga, or Al.

The metal oxide deposited at block 130 may include any atomic concentration ratio of metal constituents. For example, a binary metal alloy M1_{y}M2_{1-y} may include any atomic percent of a first metal (M1) and a complementary atomic percent of a second metal (M2), or metalloid/non-metal. A ternary alloy M1_{y}M2_{z}M3_{1-y-z} may include any atomic percent of metal M1, any atomic percent of metal M2, and a complementary atomic percent of a third metal (M3), such that y and z are both greater than 0, but sum to less than 1. In some specific embodiments, the channel material deposited at block 130 comprises comprise a zinc oxide (ZnOₓ), such as Zn(II) oxide, or ZnO, zinc peroxide (ZnO₂)m or a mixture of ZnO and ZnO₂. In some further embodiments, the oxide semiconductor material deposited at block 130 comprises ZnOₓ and indium oxide InOₓ (e.g., In₂O₃). In some further embodiments, the oxide semiconductor material deposited at block 130 is IGZO, which comprises zinc oxide, indium oxide, and gallium oxide (e.g., Ga₂O₃). The metal atomic composition ratio, for example Ga to each of In and Z (Ga:In:Z), may vary. In some examples, a Ga-rich IGZO is deposited at block 130.

The channel material deposited at block 130 may include one or more dopants such as another metal or a nonmetallic dopant, such as N, O, H, F, Cl, Si, or Ge that may introduce electron vacancies or oxygen vacancies. Whether metallic or non-metallic, most dopants can be readily detected along with the metal majority constituents by one or more chemical analysis techniques, such as X-ray photoelectron spectroscopy (XPS), energy dispersive spectroscopy (EDS), or electron energy loss spectroscopy (EELS).

Channel material deposited at block 130 may have any morphology or microstructure. In some embodiments, channel material deposited at block 130 is substantially amorphous (i.e., having no discernable long-rang order). However, depending on the substrate, the deposition process employed at block 130 may form polycrystalline (e.g., microcrystalline or nanocrystalline) metal oxide material.

Methods 101 continue at block 140 with the formation of transistor terminals and/or IC die interconnection, for example to couple terminals of multiple transistors into circuitry. Notably, block 140 may be performed before or after block 105. Hence, although FIG. 1 illustrates the formation of a source terminal and drain terminal following deposition of the channel material, any transistor terminals may instead be formed prior to formation of the channel material. For example, all terminals of a transistor structure may be formed prior to deposition of the channel material.

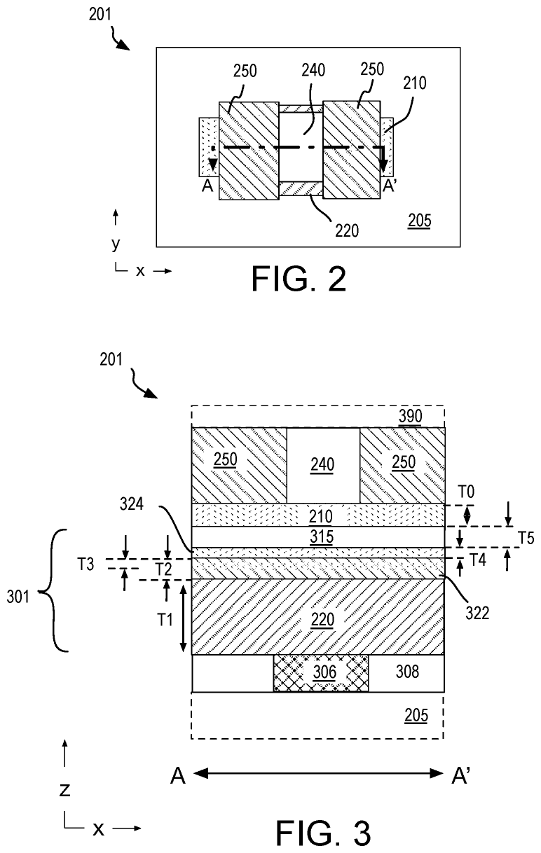

Methods 101 may be applied to a wide variety of transistor architectures. FIG. 2 is a plan view of a transistor structure 201 including a multi-composition gate dielectric, in accordance with some embodiments. In FIG. 2, heavy dot-dashed lines denote a plane A-A′ along which a cross-sectional view is further provided for various embodiments described below. Transistor structure 201 may be arrayed over an area of a device layer within IC die, for example. Transistor structure 201 is a FET with source and drain metallization 250, and a gate electrode 220, in accordance with some illustrative embodiments. Source and drain metallization 250 is electrically coupled through a channel material 210, the conductivity of which is modulated by a gate stack that further includes a gate dielectric (not illustrated). Transistor structure 201 may have a planar architecture, or a non-planar architecture. Non-planar examples include a fin structures, nanowire/ribbons or other multi-gate structures. For both planar and non-planar architectures, the channel carrier conduction may be laterally oriented in the plane of a device layer (e.g., as shown), or vertically oriented.

In FIG. 2, metal oxide channel material 210 extends over an area of a substrate 205. Although only one body of channel material 210 is illustrated in FIG. 2, a TFT may include more than one such body Channel material 210 may have any metal oxide composition, such as those described above in the context of methods 101, for example. In some embodiments, channel material 210 is IGZO, including predominantly O, In, Ga, and Zn. In specific embodiments, the atomic composition ratio of Ga to each of In and Zn is in the range of 1.5-2.5. Each of In and Zn may be at least 20 at. % of the metals present in metal oxide channel material 210. For some Ga-rich embodiments (e.g., with Ga being 40-50 at. % of the metals present in the channel material), each of In and Zn is less than 25 at. % of the metals present in metal oxide channel material 210.

As further illustrated in FIG. 2, a gate electrode 220 over/underlaps a channel region of channel material 210. Gate electrode 220 may have any composition suitable for a particular channel semiconductor material and target threshold voltage. As one example, gate electrode 220 includes one of the metal nitrides described above (e.g., TiNx).

With a lateral channel layout, source and drain metallization 250 is adjacent to gate electrode 220, and also intersects ends of channel material 210 that are on opposite sides of gate electrode 220. Source and drain metallization 250 may be in direct contact with channel material 210. Alternatively, there may be an intervening source/drain semiconductor (not depicted), which is in contact with channel material 210. Source and drain metallization 250 may include one or more metals that form an ohmic or tunneling junction directly to channel material 210, or to an intervening source/drain semiconductor material. Source and drain metallization 250 may comprise any metal. Examples include Ti, W, Ru, Pt, their alloys, and their nitrides.

FIG. 3 further illustrates TFT structure 201 along the A-A plane denoted in FIG. 2. As shown in FIG. 3, gate electrode 220 is on a bottom side of channel material 210, and source/drain metallization 250 is on a top side of channel material 210. Gate electrode 220 is embedded within a dielectric material 308, which may be any suitable material such as, but not limited to, silicon dioxide, silicon nitride, or silicon oxynitride, a low-k material (e.g., with a relative permittivity below 3.5), or a dielectric metal oxide. Dielectric material 308 is over substrate 205, which is illustrated in dashed line to emphasize that substrate 205 may include any number of FEOL material and/or circuitry levels. A conductive interconnect via 306 electrically couples gate electrode 220 to circuitry within substrate 205. Source/drain metallization 250 is embedded within a dielectric material 240, which may be any suitable material (e.g., silicon dioxide, silicon nitride, or silicon oxynitride, or a low-k material). Any number of BEOL material and/or circuitry levels 390 may be over dielectric material 240.

In the “bottom-gate” architecture illustrated for TFT 201, transistor channel length is dependent on the spacing of source/drain metallization 250, which may be defined by some minimum lithographic feature resolution (e.g., 10-20 nm pitch) Channel length is independent of gate length (e.g., x-dimension) in this bottom-gate architecture, so gate electrode 220 may extend under source/drain metallizations 250 by an arbitrary amount, and even be present under the entire area of channel material 210.

Channel material 210 may have any thickness TO, but in some exemplary embodiments is in the range of 2-10 nm. Below channel material 210 is a gate stack 301 that includes gate electrode 220 and an intervening multi-composition gate dielectric further comprising a metal oxide layer 315 proximal to channel material 210, and a metal oxide layer 324 proximal to gate electrode 220. In FIG. 3, a cap layer 322 between gate electrode 220 and metal oxide layer 324 is demarked by solid line to represent an as-deposited thickness of T2 over gate electrode 220. Cap layer 322 may have any of the compositions described above in the context of block 110 of methods 101. For example, cap layer 322 may be 1-5 nm of deposited TiNₓ. In FIG. 3, field line shading varies within cap layer 322 to illustrate that a thickness T3 of cap layer 322 proximal to metal oxide layer 324 comprises more oxygen than the remainder of cap layer thickness T2. This increased oxygen content is indicative of cap layer 322 having been oxidized, for example as described above for block 115 of methods 101. Hence, within thickness T3, cap layer 322 comprises a metal oxynitride (e.g., TiNₓO_{y}).

Metal oxide layer 324 may be deposited according to block 120 of methods 101, for example. Metal oxide layer 324 may therefore comprise the same metal as found in cap layer 322 (e.g., Ti or any of the other metals described above). For some exemplary embodiments, metal oxide layer 324 is predominantly Ti and oxygen with thickness T4 being in the range of 0.5-1 nm. Metal oxide layer 315 may be deposited according to block 125 of methods 101, for example. Metal oxide layer 315 therefore comprises a different metal (e.g., Hf, or any of the other metals described above) than metal oxide layer 324. For some exemplary embodiments, metal oxide layer 315 is predominantly Hf and oxygen (HfOₓ) with thickness T5 being in the range of 2-5 nm.

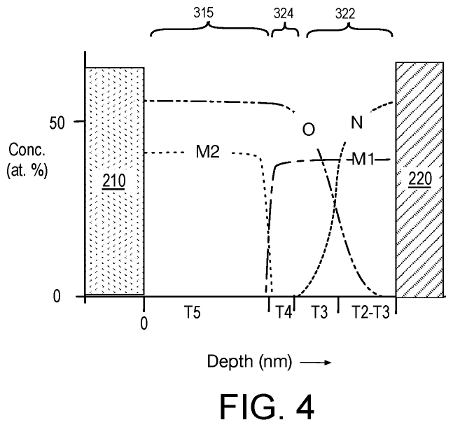

FIG. 4 is a graph illustrating compositional variation within a gate dielectric of a thin film transistor structure, in accordance with some embodiments. In FIG. 4, gate stack thicknesses are demarked on the x-axis with increasing depth from channel material 210 to gate electrode 220. As shown, within gate stack thickness T4 (corresponding to metal oxide layer 315) the composition is predominantly a metal (M2) and oxygen (O). In this example, oxygen content is over 50 at. % while metal M2 is less than 50 at. %. Within gate stack thickness T4 (corresponding to metal oxide layer 324), the composition is predominantly another metal (M1) and oxygen (O). Proximal to gate electrode 220, the gate stack composition corresponding to cap layer 322 varies with proximity to gate electrode 220 from oxygen-rich (e.g., more oxygen than nitrogen) to nitrogen-rich (e.g., more nitrogen than oxygen). Although the content of nitrogen and oxygen may vary within each of the gate stack thicknesses T3 and T2-T3, in exemplary embodiments nitrogen content is at least 50 at. % proximal to gate electrode 220 and oxygen content is at least 50 at. % proximal to metal oxide layer 324 (or channel material 210).

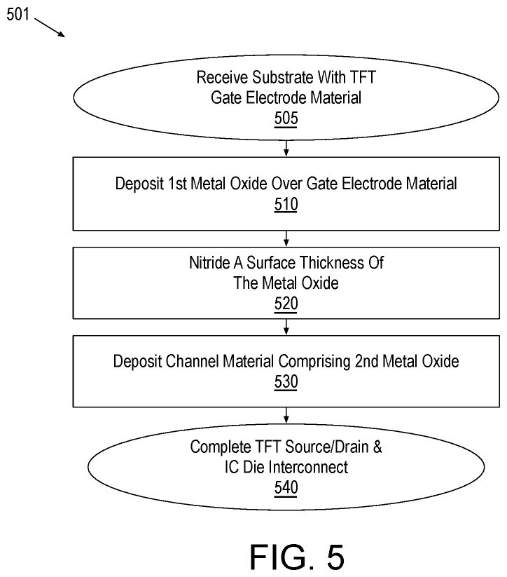

FIG. 5 is a flow diagram illustrating methods 501 of fabricating thin film transistor including a multi-composition gate dielectric, in accordance with some embodiments. Methods 501 may be practiced in the alternative to methods 101, or in combination with methods 101.

Methods 501 begin at block 505 where a substrate is received. In exemplary embodiments, the substrate includes at least a gate electrode material that is to become the gate electrode of the thin film transistor fabricated by methods 501. Methods 501 are therefore suitable for a wide variety of bottom-gate transistor architectures. The gate electrode material may have been deposited upstream of methods 501 using any technique suitable for the composition, such as PVD. In exemplary embodiments, the gate electrode material comprises at least one metal, such as Ti, W, Ta, or Al. In further embodiments, the gate electrode material comprises nitrogen (e.g., TiNₓ, WNₓ, TaNₓ, or AlNₓ) A gate electrode material may also include other constituents, such as, but not limited to, C.

Below the gate electrode material, the substrate may further include a monocrystalline semiconductor layer, such as a silicon layer, upon which front-end-of-line (FEOL) FETs have been fabricated upstream of methods 501. The substrate received at block 505 may therefore also include FEOL FETs of any architecture that are interconnected with one or more metallization levels into FEOL circuitry that is further interconnected to the gate electrode of the film transistor formed by methods 501. In some examples, the FEOL FETs include both n-type and p-type FETs interconnected into a CMOS FEOL circuit. Although the substrate received at block 505 may include FEOL FETs, the substrate may also lack any prefabricated transistors or other microelectronic devices.

Methods 501 continue at block 510 where a metal oxide MOₓ is deposited over the gate electrode material. The metal oxide is to be functional as a gate dielectric and may be any material(s) suitable for the compositions of gate electrode 220. The metal oxide deposited at block 510 is therefore a portion of the TFT gate stack. In some exemplary embodiments, a high-k metal oxide (with a bulk relative permittivity greater than 9) is deposited at block 510. The metal M, which may be one or more Hf, Zr, Al, or Ga, for example, may be deposited with an ALD process that further comprises an oxidation phase.

At block 520, nitrogen is introduced into at least a top surface of the metal oxide deposited at block 510, forming a MOₓN_{y} compound. The thickness of the MOₓN_{y} layer is a function of the duration and reactivity of the nitridation process. In some exemplary embodiments, the nitridation process entails a plasma treatment with a nitrogen source (e.g., NH₃, N₂, N₂O) performed at a process temperature not exceeding 450° C., and advantageously between 200 and 300° C. In other embodiments, the nitridation process may be purely thermal (i.e., plasma-free), in which case the process temperature may be in the range of 400-450° C., for example.

With the gate stack complete, methods 501 continue with deposition of the channel material at block 530. The channel material is also a metal oxide (i.e., a second metal oxide), but is a semiconductor. The material deposited at block 530 may have any metal oxide composition that is suitable for channel region of an operative transistor, and may be any of the channel materials described above in the context of methods 101.

In accordance with some embodiments, metal oxide channel material is deposited at block 530 with a PVD process. In accordance with other embodiments, metal oxide channel material is deposited at block 530 with an ALD process Channel material may be deposited to a thickness in the range 2-20 nm, for example. Oxide semiconductor materials primarily include one or more metals (M1, M1M2, M1M2M3, etc.) and oxygen. The metal oxide compounds may be suboxides (A₂O), monoxides (AO), binary oxides (AO₂), ternary oxides (ABO₃), and mixtures thereof, for example. In advantageous embodiments, the channel material deposited at block 530 includes oxygen and at least one of Mg, Cu, Zn, Sn, Ti, In, Ga, or Al. In some specific embodiments, the channel material deposited at block 530 comprises comprise a zinc oxide (ZnOₓ), such as Zn(II) oxide, or ZnO, zinc peroxide (ZnO₂) or a mixture of ZnO and ZnO₂. In some further embodiments, the oxide semiconductor material deposited at block 530 comprises ZnOₓ and indium oxide InOₓ (e.g., In₂O₃) In some further embodiments, the oxide semiconductor material deposited at block 530 is IGZO. The metal atomic composition ratio of IGZO may vary as embodiments are not limited in this context.

Methods 501 continue at block 540 with the formation of transistor terminals and/or IC die interconnection, for example to couple terminals of multiple transistors into circuitry. Notably, block 540 may be performed before or after block 505. Hence, although in FIG. 5 illustrates the formation of a source terminal and drain terminal following the deposition of channel material, any transistor terminals may instead be formed prior to formation of the channel material. For example, all terminals of a transistor structure may be formed prior to deposition of the channel material.

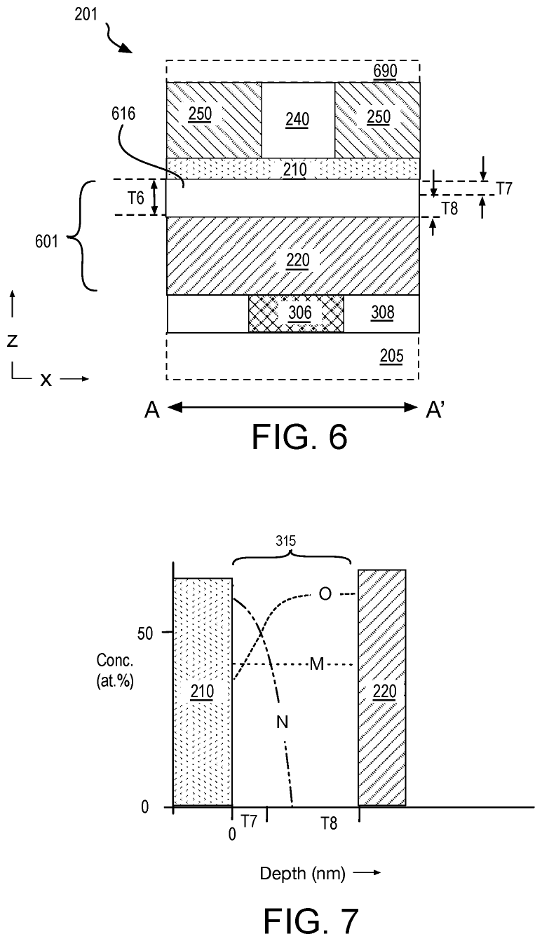

Methods 501 may be applied to a wide variety of transistor architectures. For example, methods 501 may be practiced to form a TFT with bottom-gate architecture substantially as illustrated in the plan view of FIG. 2. FIG. 6 further illustrates TFT structure 201 along the A-A plane denoted in FIG. 2 for embodiments where methods 501 are practiced to vary the composition of the gate dielectric over a thickness of the gate stack. Hence, reference numbers of features introduced in FIG. 2 for TFT structure 201 are retained in FIG. 6.

As shown in FIG. 6, gate electrode 220 is on a bottom side of channel material 210. Source/drain metallization 250 is on a top side of channel material 210. Below channel material 210 is a gate stack 601 that includes gate electrode 220 and a multi-composition gate dielectric comprising a metal oxide MOₓ layer 315, and metal oxynitride MOₓN_{y} layer 616. In FIG. 6, MOₓ layer 315 is demarked by a solid outline to illustrate an as-deposited thickness T6 over gate electrode 220.

The metal oxide MOₓ layer 315 may have any of the compositions described above in at block 510 of methods 501. For example, MOₓ layer 315 may be 3-6 nm of HfOₓ, or AlOₓ. In FIG. 6, MOₓN_{y} layer 616 is illustrated without a solid outline to emphasize this material is a portion of the as-deposited metal oxide layer 315 proximal channel material 210 of a thickness T7 where nitrogen has permeated. MOₓN_{y} layer 616 comprises more nitrogen than MOₓ layer 315. The increased nitrogen content is indicative of nitriding the MOₓ layer 315, for example as described above for block 520 of methods 501. MOₓN_{y} layer 616 may therefore comprises the same metal as found in MOₓ layer 315 (e.g., Hf or Al). For some exemplary embodiments, MOₓ layer 315 is predominantly Hf and oxygen (HfOₓ) with thickness T8 being in the range of 2-5 nm. For such embodiments MOₓN_{y} layer 616 is predominantly Hf, and at least 50% nitrogen within thickness T7. MOₓN_{y} layer thickness T7 is advantageously no more than 1.0 nm.

FIG. 7 is a graph further illustrating compositional variation within a gate dielectric of a thin film transistor structure, in accordance with some embodiments. In FIG. 7, gate stack thicknesses are demarked on the x-axis with increasing depth from channel material 210 to gate electrode 220. As shown, the composition is predominantly a metal (M) and nitrogen (N) within gate stack thickness T7 (corresponding to metal oxynitride layer 616). In this example, nitrogen content is over 50 at. % while metal M is less than 50 at. %. Within gate stack thickness T8 (corresponding to MOₓ layer 315) the composition is predominantly the metal M, and oxygen (O). In this example, oxygen content is over 50 at. % proximal to gate electrode 2200 while metal M is less than 50 at. %. Hence, the gate stack composition varies from nitrogen-rich to oxygen-rich with proximity to gate electrode 220. Relative to a reference TFT structure lacking MOₓN_{y} layer 616, capacitance of TFT 201 can be reduced by at least 10% without sacrificing drive current (Iₒₙ) performance.

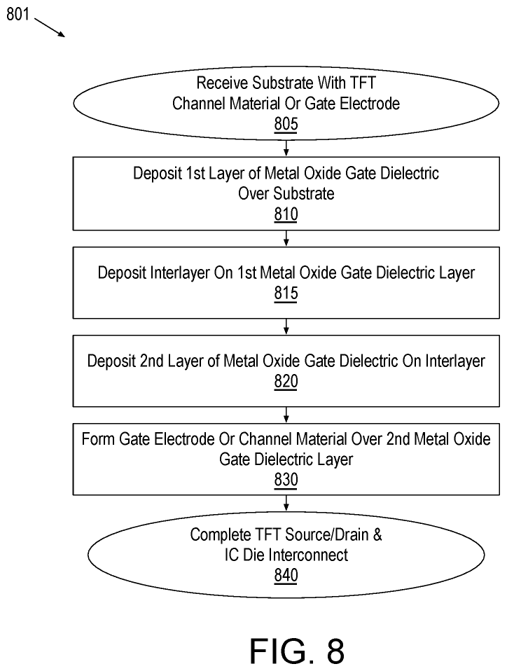

FIG. 8 is a flow diagram illustrating methods 801 of fabricating thin film transistor including a multi-composition gate dielectric, in accordance with some embodiments. Methods 801 may be practiced in the alternative to methods 101 or 501, or in combination with the practice of either (or both) of methods 101 and 501.

Methods 801 begin at input 805 where a substrate is received. The substrate may include either gate electrode material or channel material as methods 801 either a bottom-gate or top-gate TFT may be formed according to methods 801. For bottom-gate embodiments, gate electrode material is deposited upstream of methods 501, for example using any technique, such as PVD. In some exemplary bottom-gate embodiments, the gate electrode material comprises at least one metal, such as Ti, W, Ta, or Al. In further embodiments, the gate electrode material comprises nitrogen (e.g., TiNₓ, WNₓ, TaNₓ, or AlNₓ). A gate electrode material may also include other constituents, such as, but not limited to, C. For top-gate embodiments, the substrate may include any of the channel materials described elsewhere herein. In some exemplary top-gate embodiments, the channel material comprises a metal oxide, such as IGZO.

The substrate received at input 805 may further include a monocrystalline semiconductor layer, such as a silicon layer, upon which front-end-of-line (FEOL) FETs have been fabricated upstream of methods 801. The substrate received at input 805 may therefore also include FEOL FETs of any architecture that are interconnected with one or more metallization levels into FEOL circuitry that is to be further interconnected to terminals of the film transistor that is to be formed according to methods 801. In some examples, the FEOL FETs include both n-type and p-type FETs interconnected into a CMOS FEOL circuit. Although the substrate received at input 805 may include FEOL FETs, the substrate may also lack any prefabricated transistors or other microelectronic devices.

Methods 801 continue at block 810 where a first layer of metal oxide MOₓ is deposited on a surface of the gate electrode material (for bottom-gate embodiments), or on a surface of the channel material (for top-gate embodiments). The metal oxide is to be functional as a gate dielectric and may be any of material(s) described elsewhere herein. In some exemplary embodiments, a high-k metal oxide (with a bulk relative permittivity greater than 9) is deposited at block 810. The metal(s) M, which may include one or more Hf, Zr, Al, or Ga, for example, may be deposited with an ALD process that further comprises an oxidation phase.

Methods 801 continue at block 815 where an interlayer is deposited upon the first layer of metal oxide. The interlayer may be deposited by any technique suitable for the composition desired. In some embodiments, an interlayer comprising substantially silicon is deposited by PVD. In alternative embodiments, an interlayer comprising a second metal (M2) is deposited either by PVD or ALD. In one example where the second metal is Mg, an interlayer of MgOₓ is deposited by ALD. Such a layer can be deposited in-situ with the M1Oₓ deposited at block 810. In another example where the second metal is La, an interlayer of LaOₓ may be deposited at block 815, either by ALD or by PVD.

Following deposition of the interlayer, at block 820, another layer of metal oxide M1Oₓ is deposited on a surface of the interlayer. The additional layer of MOₓ advantageously includes the same metal(s) as the first layer of MOₓ deposited at block 810. In exemplary embodiments, the layers of MOₓ deposited at blocks 810 and 820 have substantially the same composition, and are deposited by the same technique. For example, at block 820 the metal(s) M may again include one or more Hf, Zr, Al, or Ga. Hence, a thickness of the interlayer is inserted between two thicknesses of the MOₓ gate dielectric.

Methods 801 continue at block 830 a channel material is deposited over the gate dielectric for bottom-gate embodiments. Alternatively, for top-gate embodiments, a gate electrode material is deposited over the gate dielectric. Accordingly, any of the gate electrode materials or channel materials described elsewhere herein may be deposited at block 830. In exemplary bottom-gate embodiments, a channel material comprising a metal oxide, such as IGZO, is deposited at block 830. In exemplary top-gate embodiments, a gate electrode material comprising at least one metal, such as Ti, W, Ta, or Al, or a nitride thereof, is deposited at block 830.

Methods 801 complete at output 840 with the formation of transistor terminals and/or IC die interconnection, for example to couple terminals of multiple transistors into circuitry. Notably, block 840 may be performed before or after block 805. Although FIG. 8 illustrates the formation of a source terminal and drain terminal following deposition of the channel material, any transistor terminals may instead be formed prior to formation of the channel material. For example, all terminals of a transistor structure may be formed prior to deposition of the channel material.

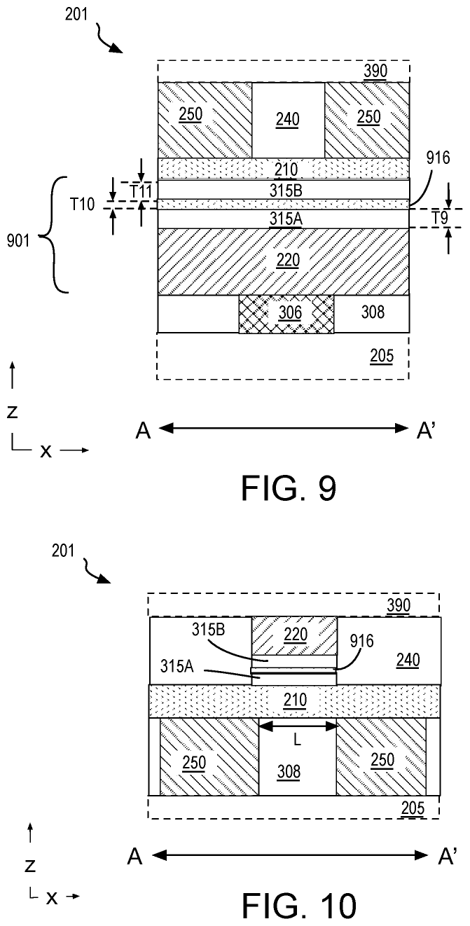

Methods 801 may be applied to a wide variety of transistor architectures. For example, methods 801 may be practiced to form a TFT with bottom-gate architecture substantially as illustrated in the plan view of FIG. 2. FIG. 9 further illustrates TFT structure 201 along the A-A plane denoted in FIG. 2 for bottom-gate embodiments where the composition of the gate dielectric is varied according to methods 801. Hence, reference number of features introduced in FIG. 2 for TFT structure 201 are retained in FIG. 9.

As shown in FIG. 9, gate electrode 220 is on a bottom side of channel material 210. Source/drain metallization 250 is on a top side of channel material 210. Below channel material 210 is a gate stack 901 that includes gate electrode 220 and a multi-composition gate dielectric comprising an interlayer 916 between an MOₓ layer 315A, and a MOₓ layer 315B. In FIG. 9, the metal oxide layers 315A and 315B are demarked by solid outlines to illustrate as-deposited thicknesses T9 and T11. Thicknesses T9 and T11 may be substantially equal, or not. Metal oxide layers 315A and 315B each may each have any of the compositions described above in the context of methods 801. For example, metal oxide layer 315A and 315B may each be 1-2 nm of HfOₓ, or AlOₓ.

In some embodiments, interlayer 916 is predominantly silicon. Alternatively, interlayer 916 comprises Mg and oxygen (MgOₓ). In some exemplary embodiments, interlay thickness T10 is less than 1 nm (e.g., 0.5-1.0 nm). For embodiments where each of thickness T9 and T10 is no more than 2 nm, the sum of thicknesses T9, T10 and T11 ranges from 4-6 nm, for example.

FIG. 10 is a cross sectional view of the transistor structure along the A-A′ line introduced in FIG. 2, in accordance with some top-gate embodiments. In FIG. 10, transistor structure 201 comprises gate electrode 220 on a top-side of channel material 210. Source/drain contact metallization 250 is on a bottom side of channel material 210. In FIG. 10, device terminals of transistor structure 201 are therefore inverted from the structure shown in FIG. 9. In FIG. 10, gate electrode 220 is embedded within dielectric material 240 while source/drain metallization 250 is embedded in dielectric material 308. In the “top-gate” architecture, gate electrode 220 may extend over source/drain metallizations 250 by an arbitrary amount. In the illustrated top-gate example, the metal oxide layers 315A, 315B and interlayer 916 may have any of the compositions and thicknesses described above in the context of FIG. 9.

Although individual transistor structures are described in detail above, any number of such structures may be fabricated concurrently and included within integrated circuitry. The various transistor structures and techniques described above are applicable to any IC architecture. In some particularly advantageous embodiments however, the transistor structures and techniques described above are employed within a 3D IC having more than one device level. In some embodiments, any of the transistor structures and techniques described above are iterated to generate two, three, or more, levels of transistors, which may all be interconnected with inter-level metallization. In some other embodiments, any of the transistor structures and techniques described above are employed at least once to fabricate a back-end device level over a front-end device level. The front-end device level may comprise any suitable CMOS circuitry that may further include transistors utilizing a Group IV semiconductor channel material, such as silicon, germanium, or SiGe alloys. Such front-end transistors may have single crystalline channel regions that employ a portion of a single crystalline substrate, for example.

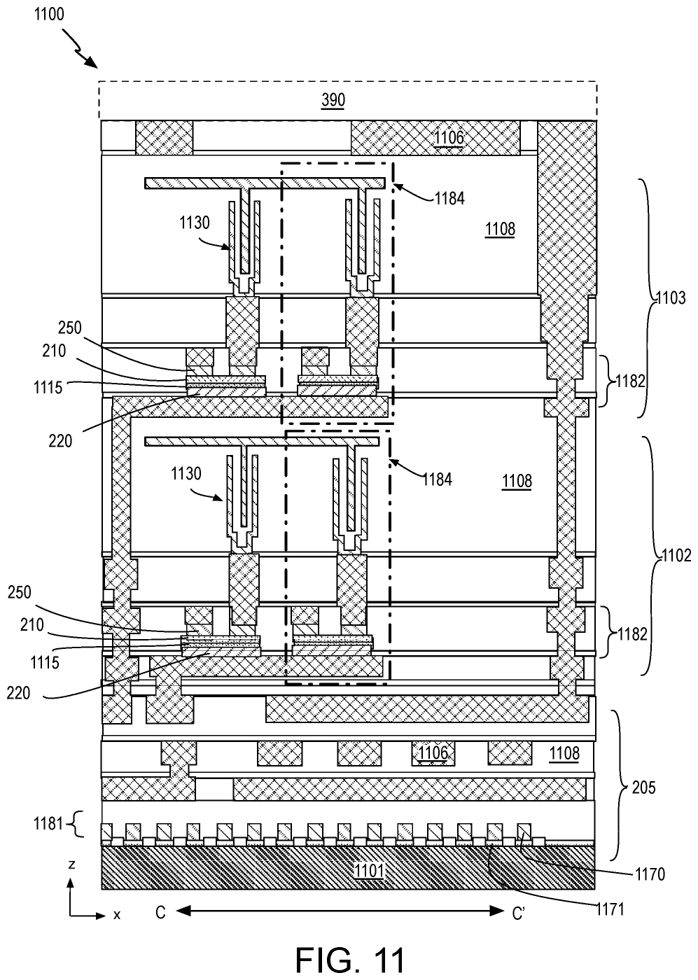

FIG. 11 illustrates a cross-sectional side view of a 3D IC structure 11900, in accordance with some embodiments. Structure 1100 illustrates a portion of a monolithic IC that includes a substrate 205 that comprises FEOL device circuitry fabricated over and/or on (e.g., single crystalline) substrate 1101. In this example, FEOL device circuitry includes a plurality of MOSFETs 1181 that employ a monocrystalline semiconductor material for at least a channel region of each transistor. FETs 1181 include a gate terminal 1170 separated from semiconductor material 1101 by a gate dielectric 1171. The channel region of semiconductor material 1101 separates semiconductor terminals (not depicted). Any materials known to be suitable for FETs may be present in FEOL FETs 1181. FETs 1181 may be planar or non-planar devices. In some advantageous embodiments, FETS 1181 are finFETs. FETs 1181 may include one or more semiconductor materials. As one example, semiconductor material 1101 is a surface layer of a substantially monocrystalline substrate.

FEOL device circuitry may further include one or more levels of interconnect metallization 1106 electrically insulated by dielectric material 1108. Interconnect metallization 1106 may be any metal(s) suitable for FEOL and/or BEOL IC interconnection (e.g., an alloy of predominantly Cu, an alloy of predominantly W, or an alloy of predominantly Ru, etc.). Dielectric material 1108 may be any dielectric material known to be suitable for electrical isolation of monolithic ICs. In some embodiments, dielectric material 1108 comprises silicon, and at least one of oxygen and nitrogen. Dielectric material 1108 may be SiO, SiN, or SiON, for example.

BEOL device circuitry 1102 is located over the FEOL device circuitry, with dielectric material 1108 therebetween. BEOL device circuitry 1102 includes a plurality of devices 1182 that employ metal oxide channel semiconductor material 210 and a gate stack, which has multiple compositions through its thickness, for example as described elsewhere herein. For the illustrated embodiments, individual ones of devices 1182 include gate electrode 220 separated from a channel region of metal oxide channel material 210 by gate dielectric 1115. Gate dielectric 1115 may have one or more of the attributes described above, for example as described for metal oxide layer 315, metal oxide layer 324 (FIG. 3), metal oxynitride MOₓN_{y} layer 616 (FIG. 6), or metal oxide layers 315A, 315B and interlayer 916 (FIG. 9). In some embodiments, devices 1182 have two or more of the attributes described above for multi-composition gate dielectrics. For example, the gate stack of devices 1182 may include the metal oxide layer 315 and metal oxide layer 324, and also include the metal oxynitride MOₓN_{y} layer 616. In another embodiment, the gate stack of devices 1182 includes the metal oxide layer 324, and also include the metal oxide layers 315A, 315B and interlayer 916. In another embodiment, the gate stack of devices 1182 includes metal oxide layers 315A, 315B and interlayer 916, and further includes metal oxynitride MOₓN_{y} layer 616. In other embodiments, devices 1182 have all of the attributes described above for multi-composition gate dielectrics. For example, the gate stack of devices 1182 may metal oxide layer 324, metal oxide layers 315A, 315B and interlayer 916, and also include the metal oxynitride MOₓN_{y} layer 616.

In the exemplary embodiment illustrated, devices 1182 are “bottom-gate” TFTs with gate electrode 220 under channel material 210. Although bottom-gate devices are illustrated, embodiments herein are also applicable top-gate transistor architectures, side-gate transistor architectures, or other planar and non-planar transistor architectures, such as any of those described elsewhere herein.

BEOL circuitry 1102 may comprise any number of metallization levels over transistor structures 1182. Any number of interconnect metallization levels may be employed to couple BEOL circuitry to the underlying FEOL device circuitry. As further shown, a metal route (e.g., via) electrically connects FEOL interconnect metallization to gate electrode 220.

In further embodiments, there may be multiple levels of BEOL device circuitry located over the FEOL device circuitry. Each level of BEOL device circuitry may include a plurality of TFTs 1182 that employ a metal oxide channel material. In the example illustrated in FIG. 11, TFTs 1182 are electrically coupled to a metal-insulator-metal (MIM) capacitor 1130. One TFT and one MIM capacitor 1130 are together functional as 1T1C memory cells 1184, denoted by a dot-dashed line. Within one memory cell 1184, one TFT 1182 is operable as a cell select transistor. A 3DIC may include any number of device layers, with the example illustrated in FIG. 1 including two metal cell levels of 1102, 1103 vertically stacked over FEOL circuitry.

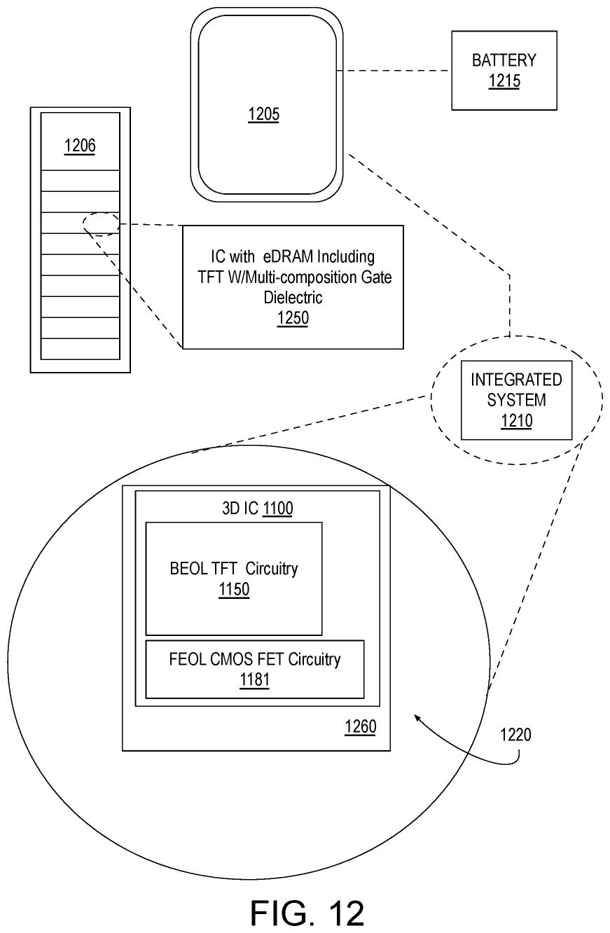

FIG. 12 illustrates a system in which a mobile computing platform 1205 and/or a data server machine 1206 employs an IC including at least one semiconductor device. The server machine 1206 may be any commercial server, for example including any number of high-performance computing platforms disposed within a rack and networked together for electronic data processing, which in the exemplary embodiment includes a packaged monolithic IC 1250. The mobile computing platform 1205 may be any portable device configured for each of electronic data display, electronic data processing, wireless electronic data transmission, or the like. For example, the mobile computing platform 1205 may be any of a tablet, a smart phone, laptop computer, etc., and may include a display screen (e.g., a capacitive, inductive, resistive, or optical touchscreen), a chip-level or package-level integrated system 1210, and a battery 1215.

Whether disposed within the integrated system 1210 illustrated in the expanded view 1220, or as a stand-alone packaged chip within the server machine 1206, a monolithic 3D IC 1100 includes a memory chip (e.g., RAM), or a processor chip (e.g., a microprocessor, a multi-core microprocessor, graphics processor, or the like) including at least one TFT including a multi-composition gate dielectric, for example as described elsewhere herein. 3D IC 1100 may further include silicon CMOS front-end circuitry with FETs 1181. The 3D IC 1100 may be further coupled to a board, a substrate, or an interposer 1260.

3D IC 1100 may have an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond.

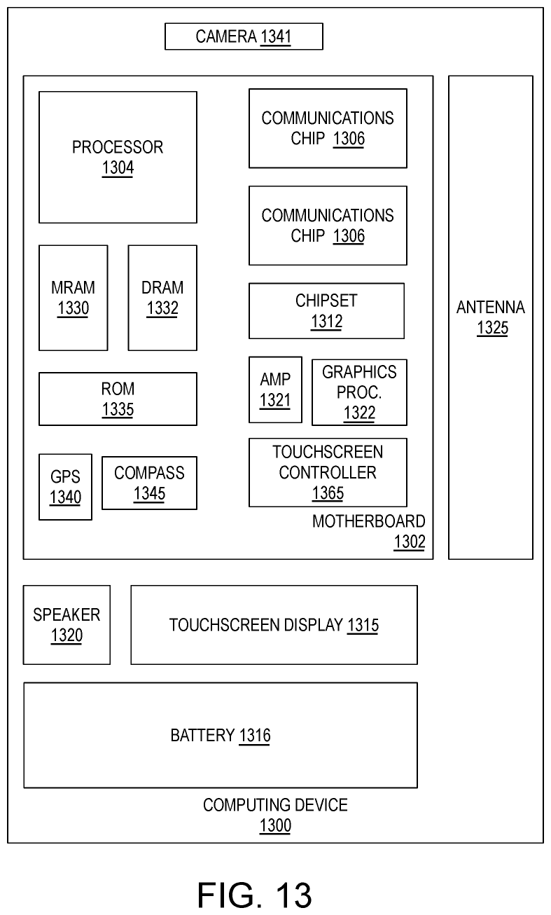

FIG. 13 is a functional block diagram of an electronic computing device 1300, in accordance with some embodiments. Device 1300 further includes a motherboard 1302 hosting a number of components, such as, but not limited to, a processor 1304 (e.g., an applications processor). Processor 1304 may be physically and/or electrically coupled to motherboard 1302. In some examples, processor 1304 includes a 3D IC structure, for example as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 1306 may also be physically and/or electrically coupled to the motherboard 1302. In further implementations, communication chips 1306 may be part of processor 1304. Depending on its applications, computing device 1300 may include other components that may or may not be physically and electrically coupled to motherboard 1302. These other components include, but are not limited to, volatile memory (e.g., DRAM 1332), non-volatile memory (e.g., ROM 1335), flash memory (e.g., NAND or NOR), magnetic memory (MRAM 1330), a graphics processor circuitry 1322, a digital signal processor circuitry, a crypto processor, a chipset 1312, an antenna 1325, touchscreen display 1315, touchscreen controller 1365, battery 1316, audio codec, video codec, power amplifier 1321, global positioning system (GPS) device 1340, compass 1345, accelerometer, gyroscope, speaker 1320, camera 1341, and mass storage device (such as hard disk drive, solid-state drive (SSD), compact disk (CD), digital versatile disk (DVD), and so forth), or the like.

Communication chips 1306 may enable wireless communications for the transfer of data to and from the computing device 1300. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1306 may implement any of a number of wireless standards or protocols, including but not limited to those described elsewhere herein. As discussed, computing device 1300 may include a plurality of communication chips 1306. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

In first examples a transistor structure, comprises a channel material comprising a plurality of metals and oxygen, a source contact and a drain contact electrically coupled to the channel material, and a gate stack comprising a gate electrode and a gate dielectric. The gate stack is in contact with a portion of the channel material between the source contact and drain contact. A first thickness of the gate stack comprises predominantly nitrogen and a metal, and a second thickness of the gate stack comprises predominantly oxygen and the metal.

In second examples, for any of the first examples the first thickness is proximal to the gate electrode and the second thickness is proximal to the channel material.

In third examples, for any of the first through second examples the first thickness comprises more nitrogen than oxygen, and the second thickness comprises more oxygen than nitrogen.

In fourth examples, for any of the third examples a third thickness of the gate stack between the channel material and the second thickness of the gate stack comprises predominantly a second metal and oxygen.

In fifth examples, for any of the fourth examples the metal is Ti, the first thickness comprises TiOₓN_{y} and y is at least 0.5, the second thickness comprises TiOₓN_{y} and x is at least 0.5, and the second metal is Hf.

In sixth examples, for any of the fifth examples the first thickness is 1-2 nm, the second thickness is 1-5 nm, and the third thickness is at least 3 nm.

In seventh examples, for any of the first through sixth examples the first thickness of the gate stack is proximal to the gate electrode and the second thickness of the gate stack is proximal to the channel material.

In eighth examples, for any of the seventh examples the first thickness comprises HfOₓ, the second thickness comprises HfOₓN_{y}, and y is at least 0.5.

In ninth examples, for any of the seventh examples the second thickness is no more than 1 nm, and a sum of the first and second thicknesses is at least 3 nm.

In tenth examples, for any of the first through ninth examples the plurality of metals of the channel material comprises In, Ga, Zn and O.

In eleventh examples, a transistor structure comprises a channel material comprising a plurality of metals and oxygen, a source contact and a drain contact electrically coupled to the channel material, and a gate stack comprising a gate electrode material and a gate dielectric. The gate stack is in contact with a portion of the channel material between the source contact and drain contact. A first thickness of the gate dielectric, proximal to the gate electrode, comprises predominantly oxygen and a first metal. A second thickness of the gate dielectric, proximate to the channel material comprises predominantly oxygen and the first metal. A third thickness of the gate dielectric, between the first and second thicknesses, comprises a second metal, or is predominantly silicon.

In twelfth examples, for any of the eleventh examples the first metal is Hf.

In thirteenth examples, for any of the twelfth examples the second metal is Mg, and the third thickness of the gate dielectric comprises Mg and O.

In fourteenth examples, for any of the eleventh examples the third thickness of the gate dielectric comprises predominantly Si.

In fifteenth examples, for any of the eleventh examples the first thickness is 1-3 nm, the second thickness is 1-3 nm, and the third thickness is less than 1 nm.

In sixteenth examples, a method of fabricating a transistor structure comprises receiving a substrate comprising a gate electrode. The gate electrode comprises a first metal. The method comprises forming a cap layer on a surface the gate electrode. The cap layer comprises the first metal and nitrogen. The method comprises oxidizing the at least a partial thickness of the cap layer, and forming a first layer comprising predominantly oxygen and the first metal over the cap layer. The method comprises forming a second layer comprising predominantly oxygen and a second metal over the first layer, and forming a channel material over the second layer, wherein the channel material comprises a plurality of metals and oxygen.

In seventeenth examples, for any of the sixteenth examples the first metal is Ti, forming of the cap layer comprises atomic layer deposition of TiNₓ, oxidizing forms TiNₓO_{y}, and forming the first layer over the cap layer comprises atomic layer deposition of TiO_{y}.

In eighteenth examples, the second layer comprises predominantly oxygen and Hf, and the plurality of metals of the channel material comprise In, Ga, Zn and O.

In nineteenth examples, a method of fabricating a transistor structure comprises receiving a substrate comprising a gate electrode, wherein the gate electrode comprises a metal, depositing a gate dielectric material upon the gate electrode. The gate dielectric comprises predominantly oxygen and a metal. The method comprises incorporating nitrogen into a partial thickness of the gate dielectric material, the partial thickness distal from the gate electrode. The method comprises forming a channel material gate dielectric, wherein the channel material comprises a plurality of metals and oxygen.

In twentieth examples, for any of the nineteenth examples incorporating nitrogen into the partial thickness of the gate dielectric material comprises performing a thermal or plasma treatment with a nitrogen source gas.

In twenty-first examples, for any of the nineteenth examples depositing the gate dielectric material comprises depositing HfOₓ, incorporating nitrogen into the partial thickness of the gate dielectric material forms a layer of HfOₓN_{y}, with y being at least 0.5.

In twenty-second examples, for any of the twenty-first examples the layer of HfOₓN_{y} has a thickness of no more than 1 nm.

In twenty-third examples a method of fabricating a transistor structure comprises receiving a substrate comprising a surface of a first of a gate electrode or a channel material, and forming a gate dielectric over the surface. Forming the gate dielectric further comprises depositing a first material layer over the surface, wherein the first material layer comprises predominantly oxygen and a first metal, depositing an second material layer on the first material layer, wherein the second material comprises Si or a second metal, and depositing a third material layer on the second material layer, wherein the third material layer comprises predominantly oxygen and the first metal. The method further comprises forming the second of the gate electrode or the channel material over the gate dielectric.

In twenty-fourth examples, for any of the twenty-third examples the first metal is Hf, and the second metal is Mg.

In twenty-fifth examples, for any of the twenty-fourth examples depositing the second material layer comprises depositing MgOₓ.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. A transistor structure, comprising:
a channel material comprising a plurality of metals and oxygen;
a source contact and a drain contact electrically coupled to the channel material; and
a gate stack comprising a gate electrode and a gate dielectric, wherein the gate stack is in contact with a portion of the channel material between the source contact and drain contact, and wherein:
a first thickness of the gate stack comprises predominantly nitrogen and a metal; and
a second thickness of the gate stack comprises predominantly oxygen and the metal.

2. The transistor structure of claim 1, wherein the first thickness is proximal to the gate electrode and the second thickness is proximal to the channel material.

3. The transistor structure of claim 2, wherein the first thickness comprises more nitrogen than oxygen, and the second thickness comprises more oxygen than nitrogen.

4. The transistor structure of claim 3, wherein a third thickness of the gate stack between the channel material and the second thickness of the gate stack comprises predominantly a second metal and oxygen.

5. The transistor structure of claim 4, wherein:
the metal is Ti;
the first thickness comprises TiOₓN_{y} and y is at least 0.5;
the second thickness comprises TiOₓN_{y} and x is at least 0.5; and
the second metal is Hf.

6. The transistor structure of claim 5, wherein:
the first thickness is 1-2 nm;
the second thickness is 1-5 nm; and
the third thickness is at least 3 nm.

7. The transistor structure of claim 1, wherein the first thickness of the gate stack is proximal to the gate electrode and the second thickness of the gate stack is proximal to the channel material.

8. The transistor structure of claim 7, wherein the first thickness comprises HfOₓ, the second thickness comprises HfOₓN_{y}, and y is at least 0.5.

9. The transistor structure of claim 7, wherein the second thickness is no more than 1 nm, and a sum of the first and second thicknesses is at least 3 nm.

10. The transistor structure of claim 1, wherein the plurality of metals of the channel material comprises In, Ga, Zn and O.

11. A transistor structure, comprising:
a channel material comprising a plurality of metals and oxygen;
a source contact and a drain contact electrically coupled to the channel material; and
a gate stack comprising a gate electrode material and a gate dielectric, wherein the gate stack is in contact with a portion of the channel material between the source contact and drain contact, and wherein:
a first thickness of the gate dielectric, proximal to the gate electrode, comprises predominantly oxygen and a first metal;
a second thickness of the gate dielectric, proximate to the channel material, comprises predominantly oxygen and the first metal; and
a third thickness of the gate dielectric, between the first and second thicknesses, comprises a second metal, or is predominantly silicon.

12. The transistor structure of claim 11, wherein the first metal is Hf.

13. The transistor structure of claim 12, wherein the second metal is Mg, and the third thickness of the gate dielectric comprises Mg and O.

14. The transistor structure of claim 12, wherein the third thickness of the gate dielectric comprises predominantly Si.

15. The transistor structure of claim 11, wherein:
the first thickness is 1-3 nm;
the second thickness is 1-3 nm; and
the third thickness is less than 1 nm.

16. A method of fabricating a transistor structure, the method comprising:
receiving a substrate comprising a gate electrode, wherein the gate electrode comprises a first metal;
forming a cap layer on a surface the gate electrode, wherein the cap layer comprises the first metal and nitrogen;
oxidizing the at least a partial thickness of the cap layer;
forming a first layer comprising predominantly oxygen and the first metal over the cap layer;
forming a second layer comprising predominantly oxygen and a second metal over the first layer; and
forming a channel material over the second layer, wherein the channel material comprises a plurality of metals and oxygen.

17. The method of claim 16, wherein:
the first metal is Ti;
the forming of the cap layer comprises atomic layer deposition of TiNₓ;
the oxidizing forms TiNₓO_{y}; and
forming the first layer over the cap layer comprises atomic layer deposition of TiO_{y}.

18. The method of claim 16, wherein:
the second layer comprises predominantly oxygen and Hf; and
the plurality of metals of the channel material comprise In, Ga, Zn and O.

19. A method of fabricating a transistor structure, the method comprising:
receiving a substrate comprising a gate electrode, wherein the gate electrode comprises a metal;
depositing a gate dielectric material upon the gate electrode, wherein the gate dielectric comprises predominantly oxygen and a metal;
incorporating nitrogen into a partial thickness of the gate dielectric material, the partial thickness distal from the gate electrode; and
forming a channel material gate dielectric, wherein the channel material comprises a plurality of metals and oxygen.

20. The method of claim 19, wherein incorporating nitrogen into the partial thickness of the gate dielectric material comprises performing a thermal or plasma treatment with a nitrogen source gas.

21. The method of claim 19, wherein:
depositing the gate dielectric material comprises depositing HfOₓ; and
incorporating nitrogen into the partial thickness of the gate dielectric material forms a layer of HfOₓN_{y}, with y being at least 0.5.

22. The method of claim 21, wherein the layer of HfOₓN_{y} has a thickness of no more than 1 nm.
